(19) United States
(12) Patent Application Publication
(10) Pub. No.: US 2002/0044578 A1
(43) Pub. Date: Apr. 18, 2002

(54) Semiconductor laser module and method for assembling the same

(75) Inventors: Shinichiro Iizuka, Tokyo (JP); Toshio Kimura, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: THE FURUKAWA ELECTRIC CO., LTD., Chiyoda-ku (JP)

(21) Appl. No.: 09/820,935

(22) Filed: Mar. 30, 2001

(30) Foreign Application Priority Data
Mar. 31, 2000 (JP) 2000-096939

(51) Int. Cl. H01S 3/04; H01S 5/00

(52) U.S. Cl. 372/36; 372/44

(57) ABSTRACT

One viewpoint of the invention intends to improve the working efficiency of fabricating a semiconductor laser module. For example, each of conductive connectors is fixed to both ends of insulation coated conductors to form conductors equipped with the conductive connectors. Pins of an inner module (case) are inserted and fixed to the conductive connectors on one end side of the insulation coated conductors. Pins of a package are inserted and fixed to the conductive connectors on the other end side. A semiconductor laser device housed inside the inner module can be conducted and connected to outside the package through the pins, the insulation coated conductors and the pins. Simple work only to insert and fix the pins to the conductive connectors can conduct and connect the pins to the pins and the working efficiency of fabricating the semiconductor laser module can be enhanced.

### BACKGROUND OF THE INVENTION

FIG. 3A depicts a top view showing one example of the internal structure of a semiconductor laser module and FIG. 3B depicts a side view showing the internal structure of the semiconductor laser module. The semiconductor laser module 1 illustrated in FIGS. 3A and 3B comprises an inner module 3 housed in a package 4, the inner module 3 containing a semiconductor laser device 2.

That is, the semiconductor laser device 2 of the inner module 3 is placed on a base 6 and the base 6 is fixed to a stem 7. On the stem 7, a cap 8 adapted to cover the semiconductor laser device 2 and the base 6 in spaced relation is mounted. The stem 7 and the cap 8 constitute a case (can) 9 and the semiconductor laser device 2 is hermetically sealed inside the case 9. On the stem 7 of the case 9, pins 10 (10a, 10b and 10c, three pins are shown in the example of the drawing) are spaced each other, the pins penetrating and protruding from inside the case to outside. The semiconductor laser device 2 sealed inside the case 9 is conducted and connected to outside the case by these pins 10.

The inner module 3 has a lens 12. The lens 12 is held by a lens holder 13 and is disposed opposite to the semiconductor laser device 2 for condensing laser lights emitted by the semiconductor laser device 2. The tip end of an optical fiber core 14 is disposed on the lens holder 13 and the laser lights condensed by the lens 12 enter the tip end of the optical fiber core 14. Here, the semiconductor laser device 2, the lens 12 and the tip end of the optical fiber core 14 are arranged coaxially.

The optical fiber core 14 is inserted and fixed to a ferrule 15. The tip end of the optical fiber core 14 is exposed to the tip end face of the ferrule 15. The tip end side of the ferrule 15 is fixed to the lens holder 13 through a slide ring 16. Thereby, the tip end of the optical fiber core 14 is spaced opposite to the lens 12.

The inner module 3 shown in FIGS. 3A and 3B is placed and fixed to a Peltier module 18 that is fixed to the bottom of the package 4. A through hole 19 is provided on the package 4 and the optical fiber core 14 of the inner module 3 is drawn from this through hole 19 to outside the package 4. A solder, for example, is disposed on a space between the end rim of the through hole 19 and the optical fiber core 14 for hermetically sealing the inside of the package 4.

A plurality of pins 20 are arranged on both side walls of the package 4, the pins 20 protruding to both inside and outside the package 4. The tip ends of the pins 10 of the inner module 3 (case 9) are conducted and connected to the tip ends of the pins 20 of the package 4, which are the counterparts to be connected, through solders 21. The semiconductor laser device 2 sealed inside the case 9 of the inner module 3 can be conducted and connected to outside the package through the pins 10 and the pins 20 of the package 4.

### SUMMARY OF THE INVENTION

One viewpoint of the present invention is to provide a semiconductor laser module having the following configuration. That is, one viewpoint of the present invention comprises:

a package comprising pins protruded to both inside and outside;

a case housed in the package, the case being formed with pins extended outside;

a semiconductor laser device sealed in the case, the semiconductor laser device being conducted to the pins of the case;

insulation coated conductors;

conductive connectors for connecting one end side of the insulation coated conductors to the pins on the side of the case and connecting the other end side of the insulation coated conductors to the pins protruded from the package to inside, wherein the semiconductor laser device is conducted and connected to outside through the pins of the case, the insulation coated conductors and the pins of the package by connection using the conductive connectors.

Additionally, another viewpoint of the invention is to provide a method for fabricating a semiconductor laser device. That is, a method for fabricating a semiconductor laser module of the invention comprising a package comprising pins protruded to both inside and outside, a case housed in the package, the case being formed with pins extended outside, and a semiconductor laser device sealed in the case, the semiconductor laser device being conducted to the pins of the case, the method comprises the steps of:

fixing each of the conductive connectors to both ends of the insulation coated conductors;

inserting and fixing the pins of the case to the conductive connectors on one end side of the insulation coated conductors;

inserting and fixing the pins of the package to the conductive connectors on the other end side of the insulation coated conductors in a similar manner; and

forming conductive paths adapted to connect the semiconductor laser device inside the case to outside the package.

### BRIEF DESCRIPTION OF THE DRAWINGS

Exemplary embodiments of the invention will now be described in conjunction with drawings, in which:

FIGS. 1A to 1C depict illustrations showing one embodiment of the semiconductor laser module of the invention;

FIGS. 2A and 2B depict diagrams showing components extracted from another embodiment of the semiconductor laser module of the invention;

FIGS. 3A and 3B depict illustrations showing one example of an orthodox semiconductor laser module; and

FIG. 4 depicts an illustration showing another example of the orthodox semiconductor laser module.

### DETAILED DESCRIPTION

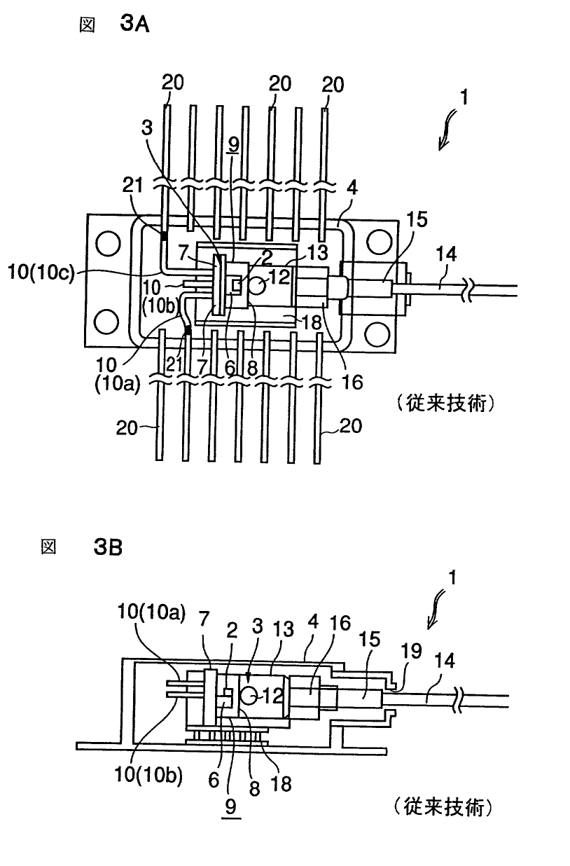

When the semiconductor laser module 1 shown in FIGS. 3A and 3B is fabricated, an orthodox operation of conducting and connecting the pins 10 of the inner module 3 to the pins 20 of the package 4 will be performed as follows. For example, in conditions of placing the inner module 3 on the Peltier module 18 that is fixed to the package 4, the tip end side of the pins 10 of the inner module 3 is first bent toward the pins 20 of the package 4 which are the counterparts to be connected and each of the tip ends of the pins 10 is abut against each of the tip ends of the pins 20. Then, the abut parts are connected by utilizing a solder 21 for conducting and connecting the pins 10 of the inner module 3 to the pins 20 of the package 4.

However, the pins 10 of the inner module 3 are fine, lacking flexibility. Besides, the interior space of the package 4 is very narrow. Thus, it is very difficult to bend the rigid pins 10 inside the narrow space of the package 4. Additionally, only the abut parts of the pins 10 against the pins 20 have to be soldered so as not to attach the solder 21 to the potion other than the part to be soldered. The soldering work requires paying close attention to it. The soldering work of the pins 10 with the pins 20 takes time. In this manner, an orthodox method for fabricating the semiconductor laser module 1 has had a problem that the working efficiency of conducting and connecting the pins 10 of the inner module 3 to the pins 20 of the package 4 is low.

Furthermore, the solder 21 is greatly sprawled out of the abut part of the pin 10 against the pin 20 and attaches to other wirings, which tends to generate the event that causes insulation failure and thus production yields of the semiconductor laser module 1 have been bad.

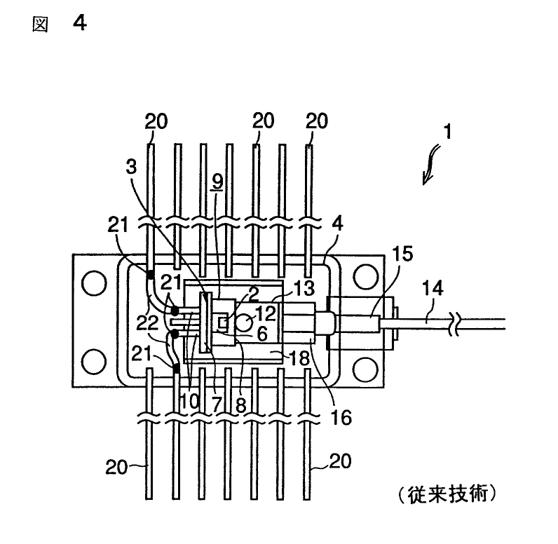

Incidentally, there is another technique of conducting and connecting the pins 10 to the pins 20 without bending the tip end side of the pins 10 of the inner module 3. This technique is illustrated in FIG. 4 in which the pins 10 are conducted and connected to the pins 20 through conductors 22 and the connection of the pins 10 to the conductors 22 and the connection of the pins 20 to the conductors 22 are performed by the solder 21.

In this case, the work to bend the tip end side of the pins 10 is not required but the soldering work is increased and thus the problem arises such that the working efficiency of conducting and connecting the pins 10 to the pins 20 is low or the production yields of the semiconductor laser module 1 is bad the same as one shown in FIGS. 3A and 3B.

Moreover, instead of the conductors 22, a technique is proposed in which the pins 10 of the inner module 3 are conducted and connected to the pins 20 of the package 4 by utilizing a wiring pattern formed on a printed circuit board or FPC (flexible printed circuit), for example. However, in this case,the pins 10 (20) are conducted and connected to the wiring pattern by utilizing the solder 21 as well and thus the problems as set forth arise. Additionally, there is a problem that costs become high. Furthermore, in this case, the wiring pattern is printed on the printed circuit board or FPC beforehand. Therefore, a problem arises that it cannot flexibly correspond to the design changes thereof in the case that the combination of connecting the pins 10 of the inner module 3 to the pins 20 of the package 4 is altered by changing specifications.

One viewpoint of the invention is to provide a semiconductor laser module with low costs capable of improving yields and the working efficiency of conducting and connecting the pins of the case in the inner module to the pins of the package and of flexibly corresponding to design changes and to provide a method for fabricating the same.

Hereafter, embodiments of the invention will be described more specifically according to drawings.

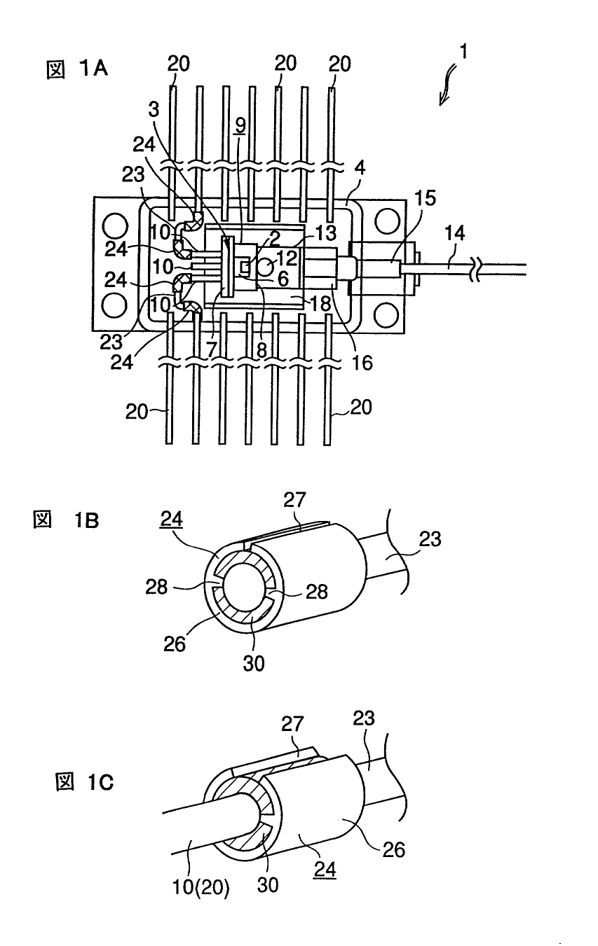

FIGS. 1A to 1C depict one embodiment of the semiconductor laser module of the invention. Additionally, in the description of the embodiment, the same components as the orthodox examples shown in FIGS. 3A, 3B and 4 are designated the same signs, omitting or simplifying the overlapping explanation of the common portions thereof.

In one embodiment of the invention, pins 10 of an inner module 3 (case 9) are conducted and connected to pins 20 of a package 4 through insulation coated conductors 23 and conductive connectors 24 are used for connecting the pins 10 (20) to the insulation coated conductors 23. The other configuration is the same as the orthodox example.

In this embodiment, the insulation coated conductors 23 are such that a conductor such as copper is coated with an insulating material and has a diameter φ of approximately 0.3 to 0.5 mm, for example, and flexibility suited to routed wiring. The following conductive connector 24 is fixed to both end sides of the insulation coated conductor 23 and the insulation coated conductor 23 comprises a conductor equipped with the conductive connectors.

The conductive connector 24, as shown in FIG. 1B, has a cylindrical member 26 made of a conductive material (copper, for example). In the embodiment, the cylindrical member 26 is provide with a split 27 along the entire length in the longitudinal direction, that is, the split 27 is disposed from one end side to the other end side of the cylindrical member. A stripped conductor on the tip end side of the insulation coated conductor 23 is inserted and fixed to one end side of the cylindrical member 26. To the other end of the cylindrical member 26, as shown in FIG. 1C, the pin 10 of the inner module 3 or pin 20 of the package 4 is inserted and fixed. In this manner, the pin 10 (20) is inserted and fixed to inside the cylindrical member 26 and thereby the insulation coated conductor 23 is conducted and connected to the pin 10 (20) through the cylindrical member 26. Additionally, in the example shown in FIG. 1A, the cylindrical member 26 of the conductive connector 24 is bent in an L shape.

In this embodiment, the inner diameter of the cylindrical member 26 is almost the same as the outer diameter of the pin 10 (20) or slightly smaller than the outer diameter of the pin 10 (20). The pin 10 (20) is inserted into inside the cylindrical member 26 and thereby the split 27 of the cylindrical member 26 is configured to expand.

Furthermore, in this embodiment, projecting parts 28 are disposed on the inner wall surface of the cylindrical member 26. As set forth, the pin 10 (20) is inserted into inside the cylindrical member 26 as it is expanding the split 27 of the cylindrical member 26. Thus, the press force of elastic recovery from the projecting parts 28 acts on the pin 10 (20) that has been inserted into inside the cylindrical member 26 to press and fix the pin 10 (20). In this manner, the projecting parts 28 have the function of pressing and fixing the pin 10 (20) that has been inserted into inside the cylindrical member 26.

Moreover, in one example, a conductively adhesive layer 30 is formed on the inner wall surface of the cylindrical member 26. The conductively adhesive layer 30 is made of a conductive material having adhesive properties, for example. As a material forming the conductively adhesive layer 30, a solder precoat, for example, is named. The conductively adhesive layer 30 is formed on the inner wall surface of the cylindrical member 26. Thereby, the pin 10 (20) that has been inserted into inside the cylindrical member 26 is pressed and fixed by the projecting parts 28 and is also bonded and fixed to the inner wall surface of the cylindrical member 26 by the conductively adhesive layer 30. Besides, an insulating material is coated on the outer surface of the cylindrical member 26 and the cylindrical member 26 is configured to secure insulation from neighboring wirings for preventing insulation failure.

The semiconductor laser module 1 shown in this embodiment is fabricated as follows. In the fabrication process of this semiconductor laser module 1, for example, the insulation coated conductors 23 equipped with the conductive connectors 24 are prepared beforehand. In conditions of placing and fixing the inner module 3 to the Peltier module 18 that is fixed to the package 4, the pins 10 of the inner module 3 are first inserted and fixed to the conductive connectors 24 on one end side of the insulation coated conductors 23. Likewise, the pins 20 of the package 4, which are the counterparts of the pins 10 to be connected, are inserted and fixed to the conductive connectors 24 on the other end side.

In this manner, each of the pins 10 of the inner module 3 is conducted and connected to the tip end of the pins 20 protruded from the side walls of the package 4 to inside, the pins 20 being the counterparts of the pins 10 to be connected. Thereby, a semiconductor laser device 2 housed inside the inner module 3 can be conducted and connected to outside the package 4 through the pins of the inner module 3, the insulation coated conductors 23 and the pins 20 of the package 4 sequentially. That is, conductive paths adapted to conduct and connect the semiconductor laser device 2 to the outside of the package 4 are formed.

After that, for example, in the case that the solder precoat is formed on the inner wall surface of the cylindrical member 26 as the conductively adhesive layer 30, a soldering iron is applied to the cylindrical member 26 of the conductive connector 24 and the cylindrical member 26 is heated to melt the solder precoat. Thereby, the pin 10 (20) that have been inserted into inside the cylindrical member 26 can be bonded and fixed to the inner wall surface of the cylindrical member 26.

Additionally, when the cylindrical member 26 is heated by utilizing the soldering iron in the case that the insulation coating material on the outer surface of the cylindrical member 26 is easily affected by heat, it is desirable to apply the soldering iron to the portion where the conductive material in the end part of the cylindrical member 26 is exposed, for example. Furthermore, as a matter of course, in the case that a material other than the solder precoat is formed as the conductively adhesive layer 30, the pin 10 (20) is bonded and fixed with the conductively adhesive layer 30 by treatment according to the constituent material of the conductively adhesive layer 30.

According to the embodiment, the pins 10 of the inner module 3 are configured to be conducted and connected to the pins 20 of the package 4 through the insulation coated conductors 23. Thus, by routing the insulation coated conductors 23, the pins 10 can be conducted and connected to the pins 20, which are the counterparts of the pins 10 to be connected, without bending the pins 10. Additionally, the conductive connectors 24 are used for connecting the pins 10 (20) to the insulation coated conductors 23 so that the pins 10 (20) can be connected to the insulation coated conductors 23 easily.

Furthermore, each of the conductive connectors 24 is fixed to both end sides of the insulation coated conductors 23. Thus, the pins 10 of the inner module 3 can be conducted and connected to the pins 20 of the package 4 with easy work where only the pins 10 of the inner module 3 are inserted into the conductive connectors 24 on one end side of the insulation coated conductors 23 and the pins 20 of the package 4 are inserted into the conductive connectors 24 on the other end side.

As mentioned above, the operation of conducting and connecting the pins 10 of the inner module 3 to the pins 20 of the package 4 can be performed simply for a short time and the working efficiency can be dramatically improved.

Moreover, the conductors for conducting and connecting the pins 10 of the inner module 3 to the pins 20 of the package 4 are the insulation coated conductors 23, the conductive connectors 24 are also coated with the insulating material and thereby insulation from neighboring wirings is surely performed. Consequently, the problems in the orthodox example, that is, the problem of insulation failure caused by sprawling the solder 21 can be prevented and the production yields can be suppressed from being bad.

Besides, in the orthodox manner, in the case that the pins 10 of the inner module 3 are connected to the pins 20 of the package 4 by utilizing the wiring pattern, the problem has arisen that the wiring pattern is difficult to be altered and it cannot flexibly correspond to design changes when the combination of connecting the pins 10 of the inner module 3 to the pins 20 of the package 4 is changed. On the contrary, the embodiment of the invention is configured in which the insulation coated conductors 23 are routed and wired to conduct and connect the pins 10 of the inner module 3 to the pins 20 of the package 4. Thus, the counterparts to be connected for the routing wiring of the insulation coated conductors 23 have only to be changed when the combination of continuity and connection is altered as set forth so that it can flexibly correspond to the design changes.

Additionally, the insulation coated conductors 23 or conductive connectors 24 are inexpensive and therefore a cost increase can be suppressed. Furthermore, as set forth, the semiconductor laser module 1 shown in the embodiment has a configuration capable of preventing the production yields from becoming bad and thus the semiconductor laser module 1 of low costs can be provided as combined with the effect of decreasing in component costs.

Moreover, in one example, the projecting parts 28 for pressing and fixing the pins are disposed on the inner wall surface of the cylindrical member 26 so that the pin 10 (20) that has been inserted into inside the cylindrical member 26 can surely be pressed and fixed. Besides, in one example, the conductively adhesive layer 30 is disposed on the inner wall surface of the cylindrical member 26 and therefore the pin 10 (20) that has been inserted into inside the cylindrical member 26 can be not only pressed and fixed but bonded and fixed to the inner wall surface of the cylindrical member 26. The pin 10 (20) that has been inserted into inside the cylindrical member 26 can be fixed more surely.

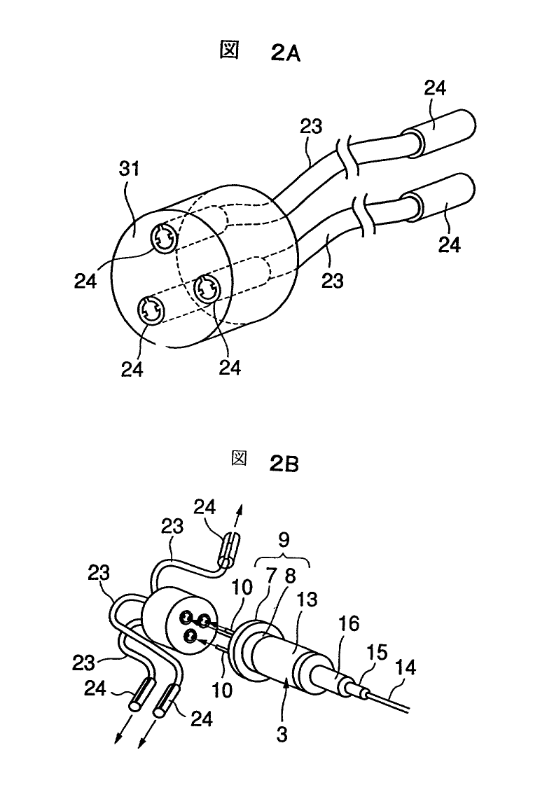

Next, another embodiment of the invention will be described. Additionally, in this embodiment, as shown in FIGS. 2A and 2B, each of conductive connectors 24 on one end side (the side to which the pins 10 of the inner module 3 are connected) of insulation coated conductors 23 equipped with a plurality of conductive connectors 24 is fixed to a common mounting member 31 and is unitized. The other configuration except this is the same as the embodiment shown in FIGS. 1A to 1C and thus the overlapping description of the common portions will be omitted. The mounting member 31 can be formed of a synthetic resin, a rubber, a metal to which a nonconductive member is applied, a porcelain and the other appropriate material.

In the embodiment shown in FIGS. 2A to 2B, each of the conductive connectors 24 on one end side of the insulation coated conductors 23 equipped with the plurality of conductive connectors 24 is fixed to the common mounting member 31. A plurality of conductive connectors 24 fixed to the mounting member 31 is adapted to insert and fix the pins 10 of the inner module 3 thereto and each of the conductive connectors 24 is arranged at a position corresponding to the position of the multiple pins 10 of the inner module 3. In this manner, the plurality of conductive connectors 24 on the side to which the inner module 3 is connected is unitized and thereby each of the corresponding multiple pins 10 of the inner module 3 can be inserted and fixed to each of the conductive connectors 24 of the unit in the block.

In the embodiment shown in FIGS. 2A and 2B, as depicted in FIG. 2B, for example, each of the corresponding pins 10 of the inner module 3 is inserted and fixed to each of the unitized conductive connectors 24 in the block and the inner module 3 equipped with the insulation coated conductors 23 is formed beforehand. Then, the inner module 3 equipped with the insulation coated conductors 23 is placed and fixed to the Peltier module 18 that is fixed to the package 4. After that, each of the conductive connectors 24 on the non-unitized side of each of the insulation coated conductors 23 is separately routed toward the pins 20, which are the counterparts to be connected, and the pins 20 to be the counterparts are inserted and fixed to the conductive connectors 24. In this manner, the pins 10 of the inner module 3 can be conducted and connected to the pins 20 of the package 4.

Additionally, each of the pins 10 of the inner module 3 may be inserted and fixed to each of the corresponding conductive connectors 24 after the inner module 3 has been placed and fixed to the Peltier module 18, the same as the embodiment shown in FIGS. 1A to 1C, not placing and fixing the inner module 3 to the Peltier module 18 after the inner module 3 equipped with the insulation coated conductors 23 has formed as set forth.

According to the embodiment shown in FIGS. 2A and 2B, without saying that the embodiment can serve the same effect as the embodiment illustrated in FIGS. 1A to 1C, the plurality of conductive connectors 24 adapted to insert and fix the pins 10 of the inner module 3 thereto is disposed on the common mounting member 31 and is unitized. Therefore, each of the multiple corresponding pins 10 of the inner module 3 can be inserted and fixed to each of the conductive connectors 24 of the unit in the block. Thereby, the working efficiency of conducting and connecting the pins 10 of the inner module 3 to the pins 20 of the package 4 can be even more enhanced.

Additionally, the invention is not limited to each of the embodiments and can adopt various forms of implementation. For example, the form of the conductive connectors 24 is not limited to the forms shown in each of the embodiments. For instance, the conductively adhesive layer 30 was disposed on the inner wall surface of the cylindrical member 26 of the conductive connector 24 shown in each of the embodiments. However, in the case that the pin 10 (20) can surely be pressed and fixed by the cylindrical member 26, the conductively adhesive layer 30 may not be disposed. Furthermore, for example, a non-conductively adhesive layer may be provided instead of the conductively adhesive layer 30. In this case, the pin 10 (20) is also configured to surely be conducted and connected to the insulation coated conductor 23 inside the conductive connector 24.

Moreover, the projecting parts 28 depicted in each of the embodiments had the form shown in FIG. 1B but the projecting parts 28 may be formed by crushing a part of the cylindrical member 26. The projecting parts 28 may not be provided when the pin 10 (20) can be fixed without the projecting parts 28. Besides, when the pin 10 (20) that has been inserted inside is pressed and fixed by crushing the entire cylindrical member 26, for example, the projecting parts 28 may not be provided necessarily but they may be provided as required.

Additionally, in each of the embodiments, the insulating material was coated on the outer surface of the conductive connectors 24. However, when there is no concern to generate insulation failure, for example, the insulating material may not be coated on the outer surface of the conductive connectors 24.

Furthermore, in each of the embodiments, each of the conductive connectors 24 was fixed on both end sides of the insulation coated conductors 23 beforehand and the operation of conducting and connecting the pins 10 of the inner module 3 to the pins 20 of the package 4 was performed by utilizing the insulation coated conductors 23 equipped with the connectors. However, for example, the connection of the insulation coated conductors 23 to the conductive connectors 24 and the connection of the conductive connectors 24 to the pins 10 (20) may be performed inside the package 4.

Moreover, the conductive connectors 24 shown in each of the embodiments were formed in a cylindrical frame. However, for example, the conductive connectors 24 may be configured in which recessed parts (or holes) for inserting and fixing the pins and recessed parts (or holes) for fixing the insulation coated conductors 23 are formed on a block body that is made of a conductive material. In this manner, the form of the conductive connectors 24 is not limited to the forms shown in each of the embodiments.

What is claimed is:

1. A semiconductor laser module comprising:
a package comprising pins protruded to both inside and outside;
a case housed in said package, the case being formed with pins extended outside;
a semiconductor laser device sealed in said case, the semiconductor laser device being conducted to the pins of said case;
insulation coated conductors; and
conductive connectors for connecting one end side of said insulation coated conductors to the pins on a side of said case and connecting the other end side of said insulation coated conductors to the pins protruded from said package to inside, wherein said semiconductor laser device is conducted and connected to outside through the pins of said case, the insulation coated conductors and the pins of the package by connection using said conductive connectors.

2. The semiconductor laser module according to claim 1 wherein the conductive connectors comprise cylindrical members made of a conductive material; and
the insulation coated conductors comprise conductors equipped with the conductive connectors where the insulation coated conductors have each of both end sides thereof inserted and fixed to one end of the cylindrical members of the conductive connectors, wherein the pins of said case are connected to the pins of the package by inserting and fixing the pins on the case side to the cylindrical members of the conductive connectors on one end side of said insulation coated conductors and by inserting and fixing the pins that are protruded from the package to inside to the cylindrical members of the conductive connectors on the other end side of said insulation coated conductors.

3. The semiconductor laser module according to claim 2 wherein projecting parts adapted to press and fix the pins that have been inserted thereto are disposed on an inner wall surface of a cylindrical frame hole of the cylindrical members of the conductive connectors.

4. The semiconductor laser module according to claim 3 wherein a conductively adhesive layer is provided on the inner wall surface of the cylindrical frame hole of the cylindrical members of the conductive connectors and the pins that have been inserted into inside the cylindrical members are pressed and fixed by the projecting parts and are bonded and fixed to the inner wall surface of the cylindrical frame hole by the conductively adhesive layer.

5. The semiconductor laser module according to claim 2 wherein a split is disposed on a part of the cylindrical members of the conductive connectors.

6. The semiconductor laser module according to claim 2 wherein a plurality of pins for conducting and connecting the semiconductor laser device is closely spaced each other; and
each of the conductive connectors on one side of a plurality of conductors equipped with the conductive connectors is fixed to a common mounting member and is unitized, wherein the plurality of pins of the aforesaid case is inserted and fixed to each of the conductive connectors of the unit in the block and each of the conductive connectors on the other end side of each of the insulation coated conductors lead out of the unit is separately routed to be inserted and fixed with the pins of the package to be counterparts.

7. The semiconductor laser module according to claim 1 wherein an outer surface of the conductive connectors is coated with an insulating material.

8. The semiconductor laser module according to claim 6 wherein at least the outer surface of the conductive connectors on the lead tip end side of each of the insulation coated conductors that are lead out of the unit is coated with the insulating material.

9. A method for fabricating a semiconductor laser module comprising a package comprising pins protruded to both inside and outside, a case housed in said package, the case being formed with pins extended outside, and a semiconductor laser device sealed in said case, the semiconductor laser device being conducted to the pins of said case, the method comprising the steps of:
fixing each of the conductive connectors to both ends of the insulation coated conductors;
inserting and fixing the pins of the case to the conductive connectors on one end side of said insulation coated conductors;
inserting and fixing the pins of the package to the conductive connectors on the other end side of said insulation coated conductors in a similar manner; and
forming conductive paths adapted to connect the semiconductor laser device in the case to outside the package.
